(19) United States
(12) Patent Application Publication
(10) Pub. No.: US 2026/0089982 A1
(43) Pub. Date: Mar. 26, 2026

(54) CAPACITOR AND METHOD OF MANUFACTURING CAPACITOR

(71) Applicants: KABUSHIKI KAISHA TOSHIBA, Kawasaki-shi (JP); Toshiba Electronic Devices & Storage Corporation, Kawasaki-shi (JP)

(72) Inventors: Hiroki KAWAKAMI, Yokohama (JP); Susumu OBATA, Yokohama (JP); Kazuhito HIGUCHI, Yokohama (JP); Takayuki TAJIMA, Sagamihara (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/300,873

(22) Filed: Aug. 15, 2025

(30) Foreign Application Priority Data
Sep. 20, 2024 (JP) 2024-163863

(51) Int. Cl. H10D 1/00; H01L 21/3213; H01L 21/683; H01L 21/78; H10D 1/66

(52) U.S. Cl. CPC H10D 1/047; H10D 1/665; H10P 50/266; H10P 54/00; H10P 72/722

(57) ABSTRACT

In general, according to one embodiment, a method of manufacturing a capacitor includes subjecting a conductive layer to dry etching to form a pattern including a connection portion extending from the conductive layer to one or more openings, and cutting a processing target substrate along a cutting position which includes a position where the connection portion is cut in a direction crossing an extending direction of the connection portion, so as to have the connection portion and a conductive material portion electrically disconnected from each other and to manufacture at least one capacitor element portion.

### CROSS-REFERENCE TO RELATED APPLICATION(S)

This application is based upon and claims the benefit of priority from Japanese Patent Application No. 2024-163863, filed Sep. 20, 2024, the entire contents of which are incorporated herein by reference.

### FIELD

Embodiments described herein relate generally to a capacitor and a method of manufacturing a capacitor.

### BACKGROUND

In the process of manufacturing a Si capacitor, trenches are formed in a Si substrate and then a dielectric film and a poly-Si film are formed, followed by patterning of the poly-Si film. The poly-Si film is patterned by, for example, chemical dry etching (CDE). The CDE is performed with the substrate to be processed, i.e., the Si substrate, clamped by an electrostatic chuck. Once the poly-Si film is patterned, the contact between the poly-Si film and the Si substrate is lost. This results in electric charges remaining at the poly-Si film, which makes the Si substrate inseparable from a stage even by dechucking, and could incur situations where damage such as a crack occurs in the Si substrate when the Si substrate is pushed up from the stage using a conductive lift pin.

### BRIEF DESCRIPTION OF THE DRAWINGS

FIG. 1 is a schematic plan view showing a first exemplary processing target substrate employed in a method according to an embodiment.

FIG. 2 is an enlarged plan view of a part of the processing target substrate shown in FIG. 1.

FIG. 3 is a sectional view of the processing target substrate shown in FIG. 2 and shows a cross-section taken along the line III-III.

FIG. 4 is a schematic circuit diagram showing a connection state of a portion which becomes a fuse portion (poly-Si fuse portion).

FIG. 5 is a plan view of the processing target substrate which undergoes a second step of the method according to the embodiment.

FIG. 6 is a sectional view of the processing target substrate shown in FIG. 5 and shows a cross-section taken along the line VI-VI.

FIG. 7 is a plan view of the processing target substrate which undergoes a third step of the method according to the embodiment.

FIG. 8 is a sectional view of the processing target substrate shown in FIG. 7 and shows a cross-section taken along the line VIII-VIII.

FIG. 9 is a schematic circuit diagram showing a connection state of the fuse portion (poly-Si fuse portion).

FIG. 10 is a plan view of the processing target substrate which undergoes a fourth step of the method according to the embodiment.

FIG. 11 is a sectional view of the processing target substrate shown in FIG. 9 and shows a cross-section taken along the line XI-XI.

FIG. 12 is a plan view of the processing target substrate which undergoes a fifth step of the method according to the embodiment.

FIG. 13 is a sectional view of the processing target substrate shown in FIG. 12 and shows a cross-section taken along the line XIII-XIII.

FIG. 14 is a plan view of the processing target substrate which undergoes a sixth step of the method according to the embodiment.

FIG. 15 is a sectional view of the processing target substrate shown in FIG. 14 and shows a cross-section taken along the line XV-XV.

FIG. 16 is a plan view of the processing target substrate which undergoes a seventh step of the method according to the embodiment.

FIG. 17 is a sectional view of the processing target substrate shown in FIG. 16 and shows a cross-section taken along the line X VII-XVII.

FIG. 18 is a plan view of the processing target substrate which undergoes an eighth step of the method according to the embodiment.

FIG. 19 is a sectional view of the processing target substrate shown in FIG. 18 and shows a cross-section taken along the line XIX-XIX.

FIG. 20 is a plan view of the processing target substrate which undergoes a ninth step of the method according to the embodiment.

FIG. 21 is a sectional view of the processing target substrate shown in FIG. 20 and shows a cross-section taken along the line XXI-XXI.

FIG. 22 is a sectional view of the vicinity of a connection portion 10 of the processing target substrate shown in FIG. 20 and shows a cross-section taken parallel to a dicing line L.

FIG. 23 is a sectional view of the vicinity of a fuse portion 8 of the processing target substrate shown in FIG. 20 and shows a cross-section taken parallel to the dicing line L.

FIG. 24 is a plan view showing a second exemplary processing target substrate employed in the method according to the embodiment.

FIG. 25 is a plan view showing a third exemplary processing target substrate employed in the method according to the embodiment.

FIG. 26 is a plan view showing a fourth exemplary processing target substrate employed in the method according to the embodiment.

FIG. 27 is a schematic diagram showing a step in which a processing target substrate to be subjected to dry etching is attached to an electrostatic chuck stage.

FIG. 28 is a schematic diagram showing a state of the processing target substrate attached to the electrostatic chuck stage.

FIG. 29 is a schematic diagram showing a state where the processing target substrate has been clamped to the electrostatic chuck stage.

FIG. 30 is a schematic diagram showing a state of the processing target substrate attached to the electrostatic chuck stage, after the dry etching.

FIG. 31 is a schematic diagram showing a state of the processing target substrate shown in FIG. 30 at the time of dechucking it from the electrostatic chuck stage.

FIG. 32 is a schematic diagram showing a state where damage has occurred to the processing target substrate at the time of dechucking it from the electrostatic chuck stage.

### DETAILED DESCRIPTION

In general, according to one embodiment, a method of manufacturing a capacitor is provided. The capacitor includes at least one capacitor element portion. The at least one capacitor element portion includes a semiconductor substrate having a main surface with one or more recesses, a conductive layer provided for the main surface and the one or more recesses of the semiconductor substrate, a dielectric layer between the conductive layer and the semiconductor substrate, a first electrode electrically connected to the conductive layer, and a second electrode electrically connected to the semiconductor substrate. The method includes:
providing, in a processing target substrate including the semiconductor substrate, the conductive layer, and the dielectric layer, one or more openings in the dielectric layer and the conductive layer present in the main surface of the semiconductor substrate;
providing a conductive material portion on the main surface located within the one or more openings;
subjecting the conductive layer to dry etching to form a pattern including a connection portion extending from the conductive layer to the one or more openings;
providing the first electrode electrically connected to the conductive layer and the second electrode electrically connected to the semiconductor substrate; and
cutting the processing target substrate along a cutting position which includes a position where the connection portion is cut in a direction crossing an extending direction of the connection portion, so as to have the connection portion and the conductive material portion electrically disconnected from each other and to manufacture the at least one capacitor element portion.

According to the embodiment, a capacitor includes:
a semiconductor substrate having a main surface with one or more recesses;
a conductive layer provided in the one or more recesses and the main surface of the semiconductor substrate;
a dielectric layer between the conductive layer and the semiconductor substrate;
a connection portion connected to the conductive layer that is located in the main surface of the semiconductor substrate;
an opening separate from the connection portion and having a bottom wall which is located in the main surface of the semiconductor substrate; and
a conductive material portion provided in the opening.

Embodiments will be described in detail with reference to the drawings. Note that the description will use, in connection with all the drawings, the same reference signs for elements or components that provide the same or similar functions so that repetitive explanations will be omitted.

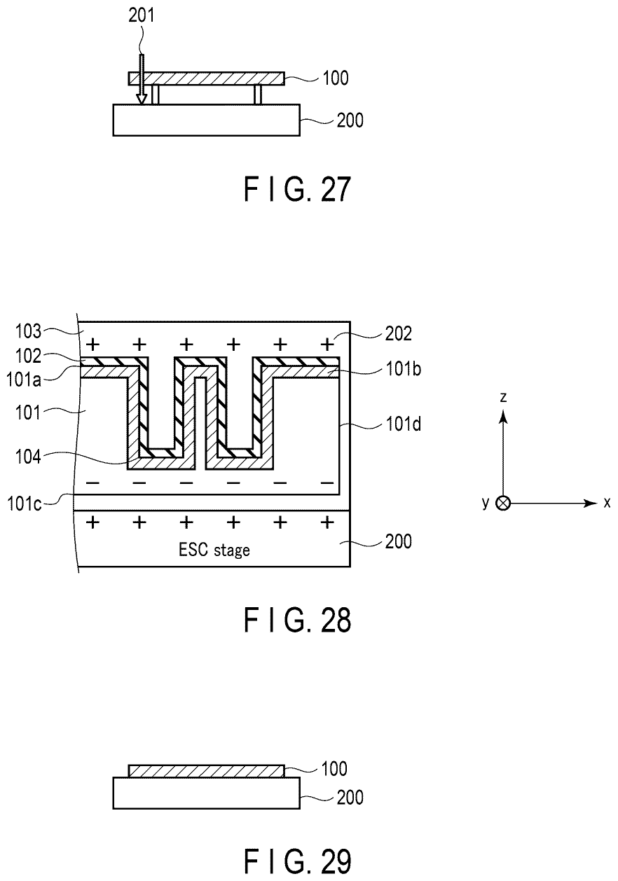

Dry etching is performed in a state where a processing target substrate is clamped to a stage of an electrostatic chuck (ESC) in a reaction chamber. The electrostatic chuck utilized in the dry etching process will be described with reference to FIGS. 27 to 32.

FIG. 27 is a schematic diagram showing a step in which a processing target substrate to be subjected to the dry etching is attached to an electrostatic chuck stage. First, a processing target substrate 100 before undergoing the dry etching is pressed against an electrostatic chuck stage 200 by a conductive lift pin 201.

As shown in FIG. 28, the processing target substrate 100 includes a semiconductor substrate 101, a dielectric layer 102, and a conductive layer 103. The semiconductor substrate 101 is a Si wafer having an impurity-doped layer 101b over its one main surface 101a. This main surface 101a of the semiconductor substrate 101 includes multiple recesses (trenches) 104. The recesses (trenches) 104 each have a depth direction along a z-axis direction. Also, the recesses (trenches) 104 are arranged apart from each other and along an x-axis direction. Each recess (trench) 104 extends along a y-axis direction.

The dielectric layer 102 is provided on the main surface 101a of the semiconductor substrate 101 and the inner surfaces of the respective recesses 104. The conductive layer 103 fills each recess 104. The conductive layer 103 covers the dielectric layer 102 located within the recesses 104 and the dielectric layer 102 located on the main surface 101a of the semiconductor substrate 101.

The conductive layer 103 also covers an opposite main surface 101c and an end surface 101d connecting the two main surfaces 101a and 101c. In one example, the conductive layer 103 is formed of poly-Si doped with impurities. Thus, by bringing the conductive lift pin 201 of the electrostatic chuck into contact with the processing target substrate 100 as shown in FIG. 27, charges 202 from the electrostatic chuck can be accumulated in the conductive layer 103. This causes the semiconductor substrate 101 of the processing target substrate 100 to be electrostatically adsorbed to the electrostatic chuck stage 200 as shown in FIG. 29. The conductive layer 103 accordingly establishes electric conduction with the electrostatic chuck stage 200. This state permits the charges 202 that remain in the conductive layer 103 to be discharged from the conductive layer 103 to the stage at the time of detaching the processing target substrate 100 from the electrostatic chuck using the pushing-up action of the conductive lift pin 201.

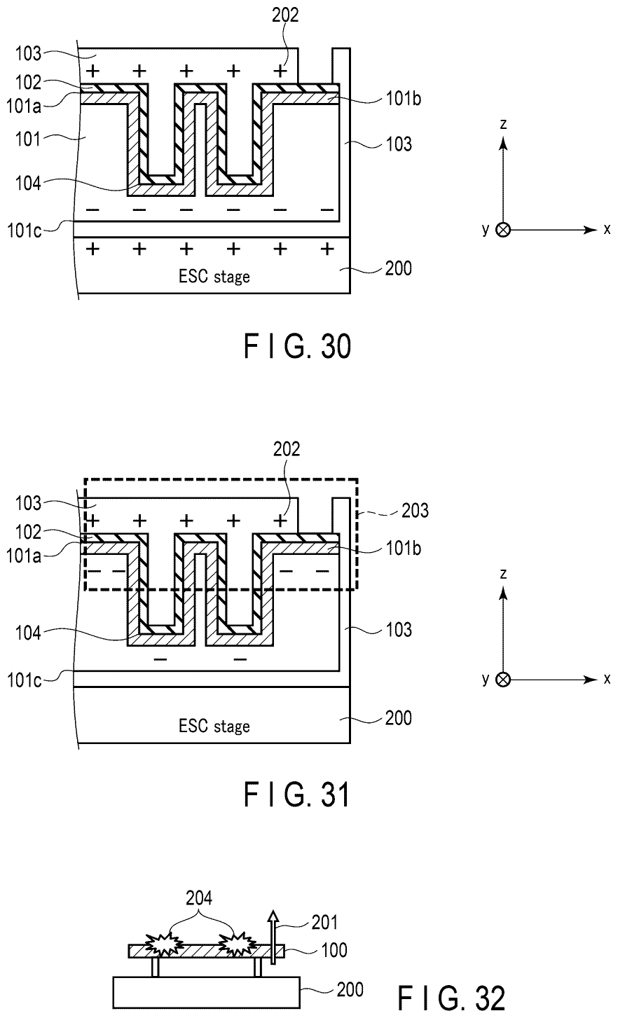

However, once the conductive layer 103 is patterned by dry etching, the electrical conduction between the conductive layer 103 and the electrostatic chuck stage 200 is disrupted as shown in FIG. 30. This results in residual charges 202 in the conductive layer 103 as shown in FIG. 31. The figure shows, as a region where the charges 202 remain, a region 203 by a dotted frame. Due to this, pushing up the processing target substrate 100 with the conductive lift pin 201 cannot cause the discharge, and the processing target substrate 100 is not released from the state of being electrostatically adsorbed to the stage 200, and consequently, damage 204 such as a crack occurs in the semiconductor substrate 101 of the processing target substrate 100 as shown in FIG. 32. Note that if the processing target substrate 100 does not include the dielectric layer 102, charges 202 accumulated in the conductive layer 103 would leak to the stage 200 through the semiconductor substrate 101 even after the patterning of the conductive layer 103 by dry etching. As such, the dechucking failure problem does not occur in this case.

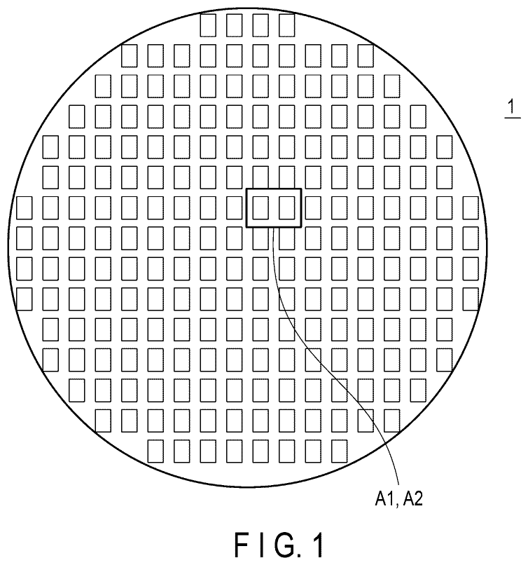

A method of manufacturing a capacitor according to an embodiment will be described with reference to FIGS. 1 to 26. Each figure assumes the z-axis direction to be a direction parallel to the thickness direction of the semiconductor substrate, the x-axis direction to be a direction parallel to the main surfaces of the semiconductor substrate, and the y-axis direction to be a direction parallel to the main surfaces of the semiconductor substrate and perpendicular to the x-axis direction. Table 1 is set forth below to show connection states of a fuse portion from first to tenth steps.

### First Step

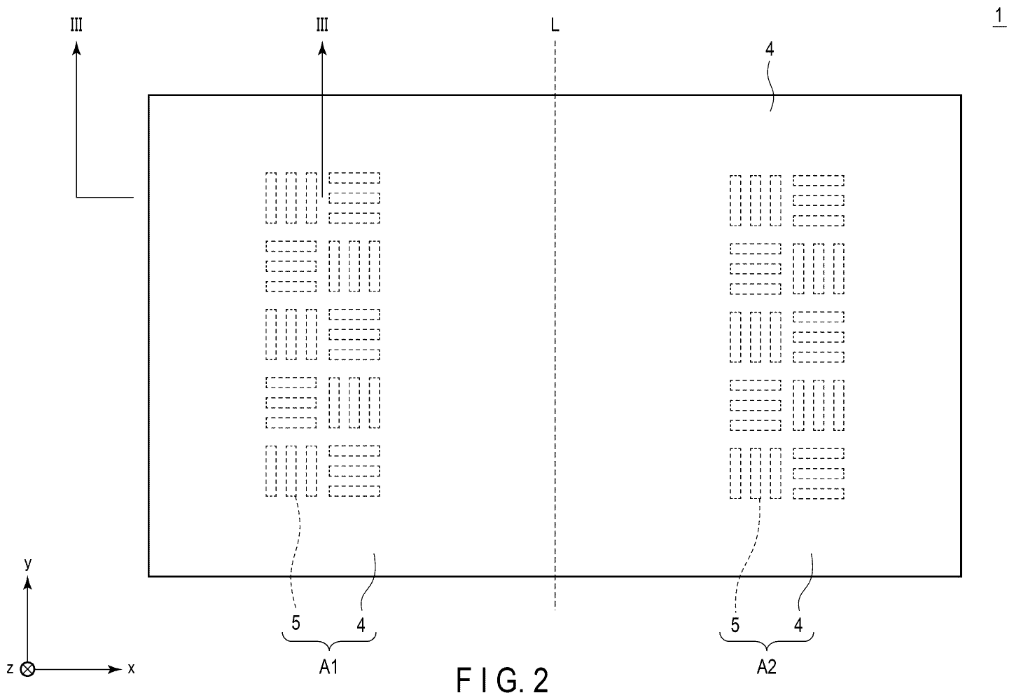

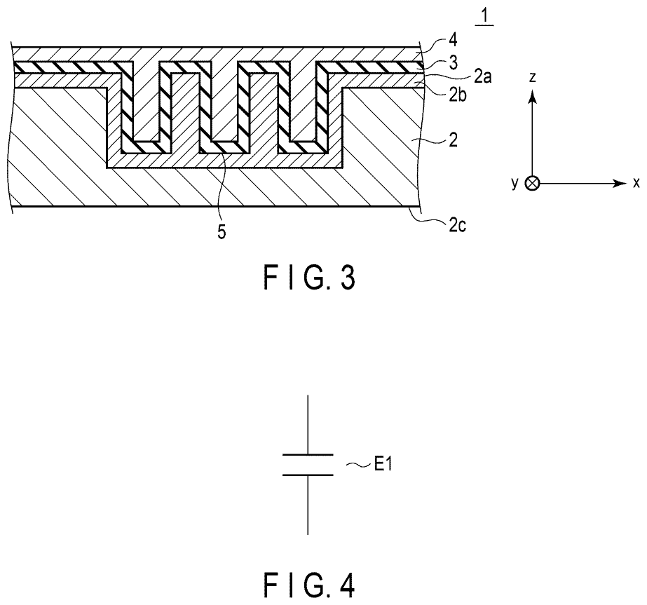

The first step includes providing a dielectric layer and a first conductive layer on a semiconductor substrate having one or more recesses in one main surface. Referring to FIGS. 1 to 4, a description will be given of the first step. FIG. 1 is a plan view of a processing target substrate. FIG. 2 is a plan view of a part of the processing target substrate. FIG. 3 is a sectional view of the processing target substrate shown in FIG. 2 and shows a cross-section taken along the line III-III. FIG. 4 is a schematic circuit diagram showing a connection state of a portion which becomes a fuse portion (poly-Si fuse portion).

The processing target substrate 1 shown in FIG. 1 includes a semiconductor substrate 2, a dielectric layer 3, and a first conductive layer 4. In one example, the semiconductor substrate 2 is a semiconductor wafer. The processing target substrate 1 will be cut along dicing lines so as to be divided into multiple capacitor element portions (multiple capacitor element chips) in a later-described cutting step. FIG. 1 denotes two neighboring capacitor element portions as A1 and A2. What is shown in FIG. 2 is an enlarged plan view of the two capacitor element portions A1 and A2 shown in FIG. 1. Each capacitor element portion may also be called a “capacitor element chip”. The two capacitor element portions A1 and A2 are arranged along the x-axis direction. A dicing line L is parallel to the y-axis direction and positioned on the boundary between the two capacitor element portions A1 and A2.

The semiconductor here is selected from, for example: silicon (Si); germanium (Ge); a semiconductor made of a compound of a Group III element and a Group V element such as gallium arsenide (GaAs) or gallium nitride (GaN); and silicon carbide (SiC). Note that the term “Group” used herein refers to a group in the short-form periodic table.

The semiconductor wafer may be doped with an impurity or impurities, and may be provided with one or more semiconductor devices including a transistor, a diode, etc. The semiconductor wafer may have a main surface parallel to any crystal plane of the semiconductor. For example, the semiconductor wafer may be a Si wafer (silicon wafer) having a (100) plane as the main surface, or a Si wafer (silicon wafer) having a (110) plane as the main surface.

FIG. 3 is a sectional view of the processing target substrate 1 shown in FIG. 2 and shows a cross-section taken along the line III-III. The semiconductor substrate 2 is a Si wafer having a P-type or N-type impurity-doped layer 2b over its one main surface 2a. This main surface 2a of the semiconductor substrate 2 includes multiple recesses (trenches) 5. The recesses (trenches) 5 may be formed by, for example, metal-assisted chemical etching (MacEtch). The recesses (trenches) 5 each have a depth direction along the z-axis direction. Among the recesses 5, some recesses 5 are arranged apart from each other and along the x-axis direction, and other recesses 5 are arranged apart from each other and along the y-axis direction. A pattern in which the recesses 5 are arranged along the x-axis direction and a pattern in which the recesses are arranged along the y-axis direction are alternately provided along each of the x-axis direction and the y-axis direction. Note that FIG. 3 shows the pattern including the x-axis direction-arranged recesses 5, and the pattern including the y-axis direction-arranged recesses 5 is not shown.

The dielectric layer 3 is provided on the main surface 2a of the semiconductor substrate 2 and the inner surfaces of the respective recesses 5. In one example, the dielectric layer 3 is made of an organic dielectric or an inorganic dielectric. As the organic dielectric, for example, polyimide may be used. As the inorganic dielectric, a ferroelectric may be used, but examples of the inorganic dielectric layer may include an oxide film, a nitride film, and so on. Paraelectrics such as silicon nitride, silicon oxide, silicon oxynitride, titanium oxide, and tantalum oxide are preferred. These paraelectrics entail small changes in dielectric constant with temperature. Accordingly, use of such paraelectrics for the dielectric layer can realize an enhanced heat resistance of the capacitor.

The first conductive layer 4 fills each recess 5. Also, the first conductive layer 4 contacts the dielectric layer 3 within the recesses 5. The first conductive layer 4 covers the dielectric layer 3 located on the main surface 2a of the semiconductor substrate 2. The first conductive layer 4 that fills each recess 5 is continuous with the first conductive layer 4 that is disposed on the main surface 2a of the semiconductor substrate 2 via the dielectric layer 3. As such, portions of the first conductive layer 4 embedded within the respective recesses 5 are electrically connected to each other. In one example, the first conductive layer 4 is formed of poly-Si (poly-silicon) doped with an impurity or impurities. The impurity-doped poly-Si shows low resistance characteristics. As one example, the impurities here may be P-type impurities or N-type impurities. The first conductive layer 4 is not limited to the poly-Si, but may be formed of, for example, a metal such as molybdenum, aluminum, gold, tungsten, platinum, nickel, or copper, or an alloy of any of such metals. The first conductive layer 4 may be of a single-layered structure or a multi-layered structure.

Note that the dielectric layer 3 and the first conductive layer 4 may also be formed on, in addition to the main surface 2a of the semiconductor substrate 2, the other main surface 2c of the semiconductor substrate 2 and an end surface connecting the main surfaces 2a and 2c.

No fuse portion has been provided for the processing target substrate 1 yet. Therefore, a portion which becomes a fuse portion is in a state E1 as shown in FIG. 4, in which the first conductive layer 4, the dielectric layer 3, and the semiconductor substrate 2 are constituting a capacitor of a metal-insulator-metal (MIM) structure.

### Second Step

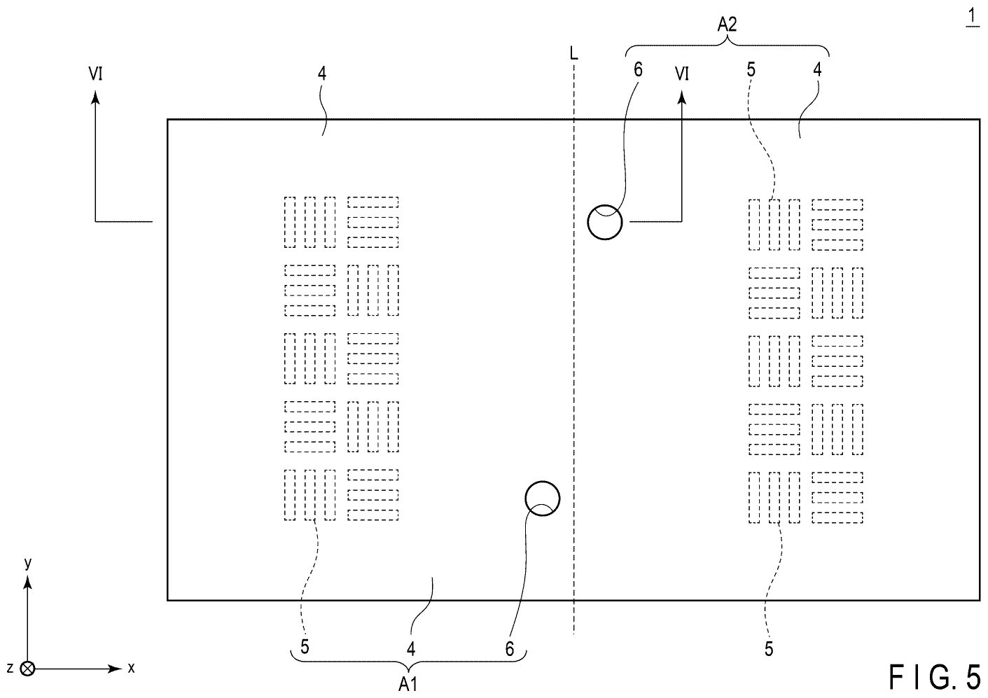

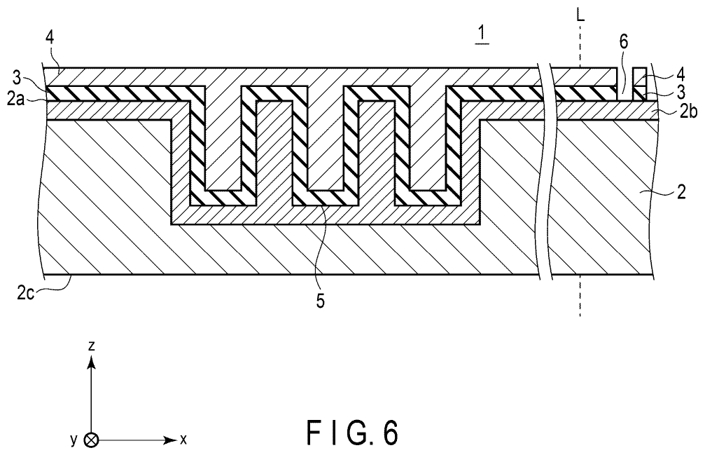

The second step includes providing one or more openings in the dielectric layer and the first conductive layer located on the main surface of the semiconductor substrate. Referring to FIGS. 5 to 6, a description will be given of the second step. FIG. 5 is a plan view of the processing target substrate. FIG. 6 is a sectional view of the processing target substrate shown in FIG. 5 and shows a cross-section taken along the line VI-VI. FIG. 6 shows the pattern including the x-axis direction-arranged recesses 5. In FIG. 6, the pattern including the y-axis direction-arranged recesses 5 is not shown.

One or more openings 6 are formed to penetrate through the dielectric layer 3 and the first conductive layer 4 located on the main surface 2a of the semiconductor substrate 2. It is desirable to provide the openings 6 at locations away from the regions where the patterns of the recesses 5 are formed. In the example shown in FIG. 5, the opening 6 is formed on the main surface 2a side of the semiconductor substrate 2 for each of the one capacitor element portion A1 and the other capacitor element portion A2 having the dicing line L along their boundary. The two openings 6 are each positioned between the region where the patterns of the recesses 5 of the one capacitor element portion A1 are formed and the region where the patterns of the recesses 5 of the other capacitor element portion A2 are formed. Each opening 6 is a cylindrical cavity having the dielectric layer 3 and the first conductive layer 4 as the inner wall and the main surface 2a of the semiconductor substrate 2 as the bottom wall. The opening 6 constitutes the fuse portion, but the fuse portion is not complete as of the end of the second step. As such, the portion which becomes the fuse portion stays in the state E1 in which the capacitor of an MIM structure as in the first step is formed.

While FIGS. 5 and 6 assume the formation of one opening 6 in each of the capacitor element portions A1 and A2, no limitation is intended by this, and multiple openings 6 may be provided.

The openings 6 may be formed by, for example, dry etching such as chemical dry etching (CDE). Examples of CDE include reactive ion etching (RIE).

The dry etching is conducted with the processing target substrate 1 held by an electrostatic chuck (ESC chuck). In one example, the first conductive layer 4 is formed of impurity-doped poly-Si, and accordingly, the first conductive layer 4 is capable of accumulating charges from the electrostatic chuck. This causes the semiconductor substrate 2 of the processing target substrate 1 to be electrostatically adsorbed to the electrostatic chuck stage. Although not shown in the figures, the first conductive layer 4 is also formed on, in addition to the main surface 2a of the semiconductor substrate 2, the other main surface 2c of the semiconductor substrate 2 and the end surface connecting the main surfaces 2a and 2c. Thus, electric conduction is established between the first conductive layer 4 and the electrostatic chuck stage. After the dry etching, charges that remain in the first conductive layer 4 can be allowed to escape from the first conductive layer 4 to the stage at the time of detaching the processing target substrate 1 from the electrostatic chuck using the pushing-up action of a conductive lift pin, and therefore, it is possible to avoid the occurrence of damage in detaching the processing target substrate 1 from the electrostatic chuck.

### Third Step

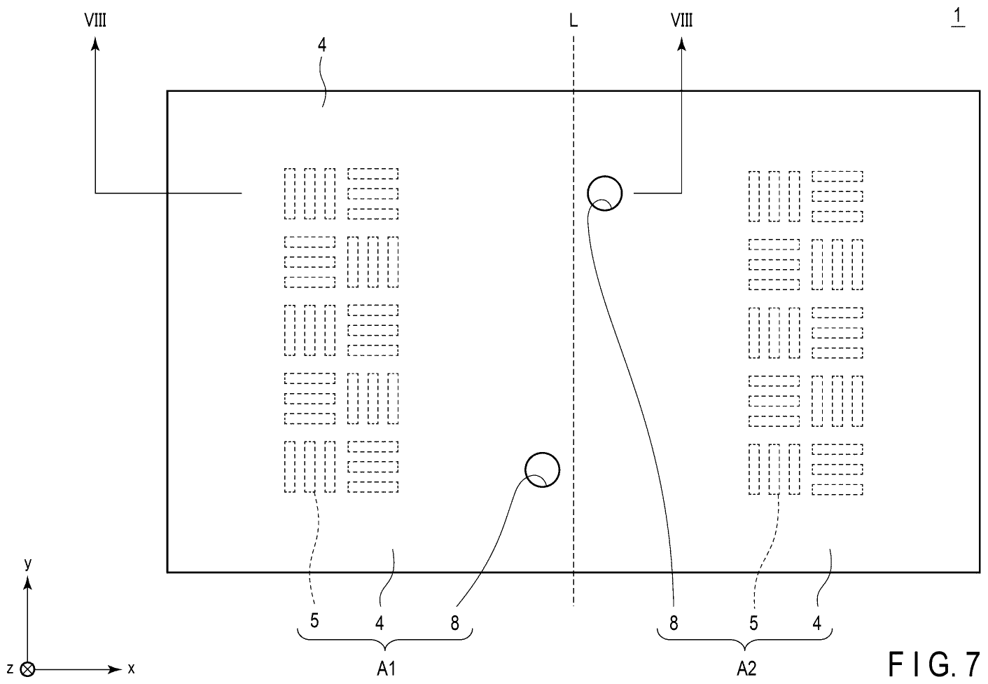

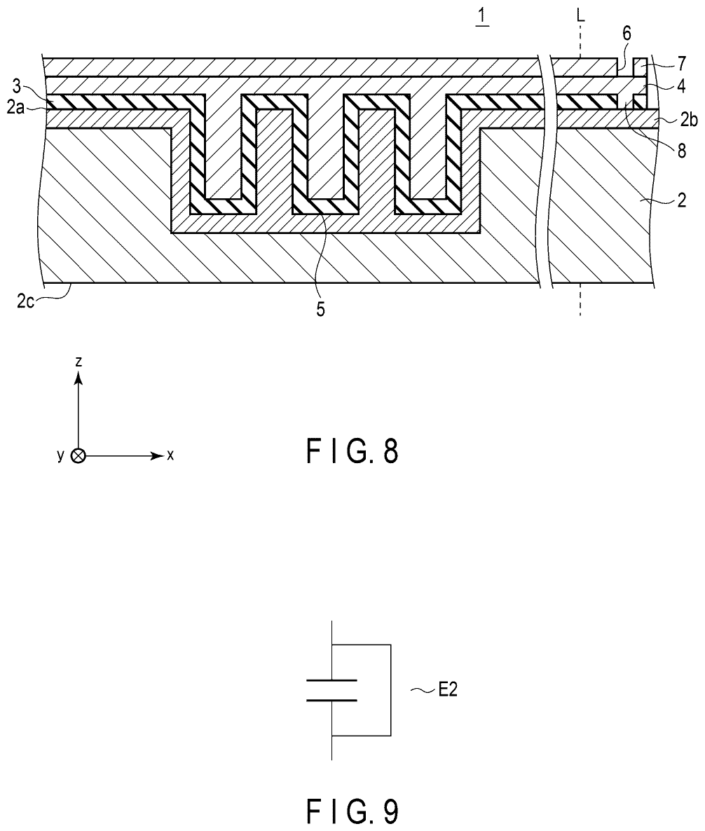

The third step includes providing a conductive material portion in the opening. The conductive material portion constitutes the fuse portion (for example, a poly-Si fuse portion). The third step will be described with reference to FIGS. 7 to 9. FIG. 7 is a plan view of the processing target substrate. FIG. 8 is a sectional view of the processing target substrate shown in FIG. 7 and shows a cross-section taken along the line VIII-VIII. FIG. 9 is a schematic circuit diagram showing a connection state of the fuse portion (poly-Si fuse portion).

For each of the capacitor element portions A1 and A2 of the processing target substrate 1, a second conductive layer 7 is provided on the first conductive layer 4 located on the entire surface of the main surface 2a of the semiconductor substrate 2. Here, a conductive material portion 8 made of the same material as that of the second conductive layer 7 is embedded in the opening 6 of each of the capacitor element portions A1 and A2. The conductive material portion 8 is in direct contact with the main surface 2a of the semiconductor substrate 2 located within each opening 6. The conductive material portion 8 is also in contact with the first conductive layer 4. Thus, electric conduction is established between the first conductive layer 4 and the semiconductor substrate 2 via the conductive material portion 8. The conductive material portion 8 may also be referred to as a “fuse portion (poly-Si fuse portion)”. The fuse portion (poly-Si fuse portion) of each of the capacitor element portions A1 and A2 has an electrical connection state E2 as shown in FIG. 9, in which the first conductive layer 4 is directly electrically connected to the semiconductor substrate 2.

In one example, the second conductive layer 7 may be formed of the same material as that of the first conductive layer 4. Note that, while FIG. 8 shows a boundary between the first conductive layer 4 and the second conductive layer 7 for facilitating understanding, the boundary (interface) between the first conductive layer 4 and the second conductive layer 7 may often be vague.

### Fourth Step

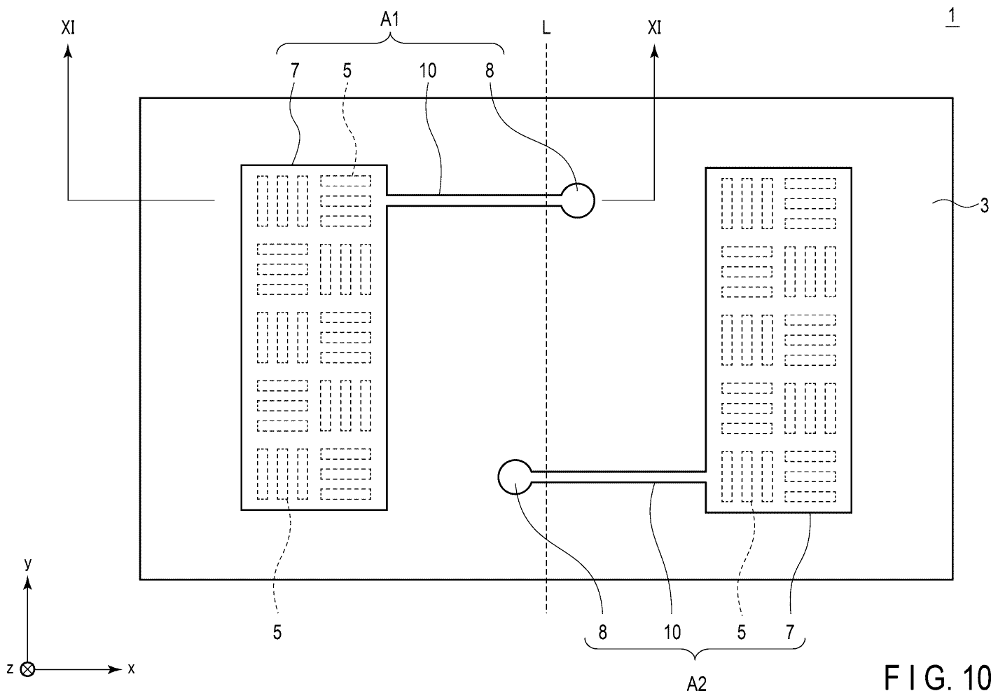

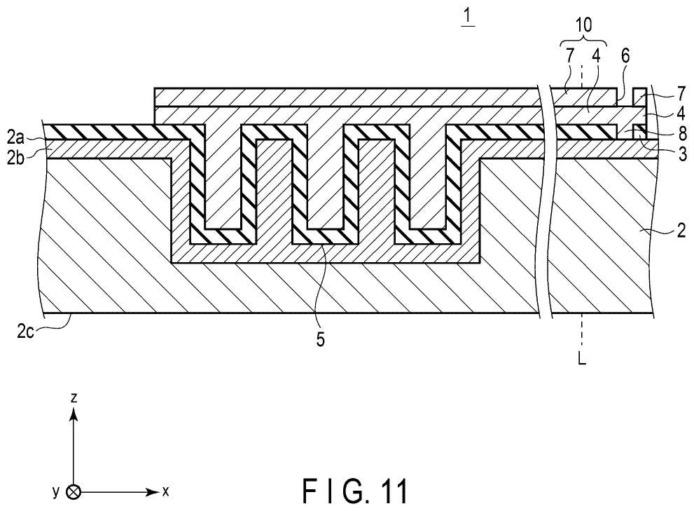

The fourth step includes patterning the first conductive layer and the second conductive layer by dry etching. The fourth step will be described with reference to FIGS. 10 to 11. FIG. 10 is a plan view of the processing target substrate. FIG. 11 is a sectional view of the processing target substrate shown in FIG. 10 and shows a cross-section taken along the line XI-XI.

For each of the capacitor element portions A1 and A2 of the processing target substrate 1, the first conductive layer 4 and the second conductive layer 7 are processed into a patterned shape by dry etching. The dry etching may be performed after mask formation by photolithography. The patterning is performed for the purpose of partitioning the first conductive layer 4 and the second conductive layer 7 for each chip. Both of the first conductive layer 4 and the second conductive layer 7 of the each chip may have a target area for one chip. However, processing the first conductive layer 4 and the second conductive layer 7 into a target area could disrupt the electrical conduction between the first conductive layer 4 and the fuse portion 8. Thus, the patterning is performed while forming a connection portion (interconnect portion) 10 for keeping electrical conduction between the first conductive layer 4 and the fuse portion 8. More specifically, in each of the capacitor element portions (capacitor element chips) A1 and A2, the first conductive layer 4 and the second conductive layer 7 are removed by dry etching, except a part corresponding to the region where the patterns of the recesses 5 are formed and a part extending in the x-axis direction from this part and reaching the fuse portion 8. Each connection portion 10 is constituted by the directly extending part of the first conductive layer 4 and the second conductive layer 7. The connection portion 10 extends in the direction parallel to the x-axis direction and crossing the direction of the dicing line L, and is connected to the opening 6. The connection portion 10 is present at the inner wall of the opening 6. The fuse portion 8 embedded in the opening 6 is in contact with the connection portion 10 present at the inner wall of opening 6. The fuse portion 8 is also in contact with the main surface 2a of the semiconductor substrate 2 located at the bottom wall of the opening 6. As such, the first conductive layer 4 and the second conductive layer 7 are electrically connected to the semiconductor substrate 2 via the connection portion 10 and the fuse portion 8. The fuse portion (poly-Si fuse portion) 8 here shows the electrical connection state E2 as in the third step.

Examples of the dry etching here may include the same etching techniques discussed for the third step.

The dry etching is conducted with the processing target substrate 1 held by the electrostatic chuck (ESC chuck). After the dry etching, charges that remain in the first conductive layer 4 and the second conductive layer 7 can be allowed to flow from the fuse portion 8 to the semiconductor substrate 2 and escape from the semiconductor substrate 2 to the stage at the time of detaching the processing target substrate 1 from the electrostatic chuck using the pushing-up action of the conductive lift pin, and therefore, it is possible to avoid the occurrence of damage in detaching the processing target substrate 1 from the electrostatic chuck.

In this relation, the processing target substrate 1 including the fuse portions 8 was detached from an electrostatic chuck after patterning the conductive layers by reactive ion etching with the processing target substrate 1 clamped to the electrostatic chuck. The result of repeating this detaching operation 10 times was that the processing target substrate was able to be detached from the electrostatic chuck without the occurrence of any damage such as cracks in all the instances.

### Fifth Step

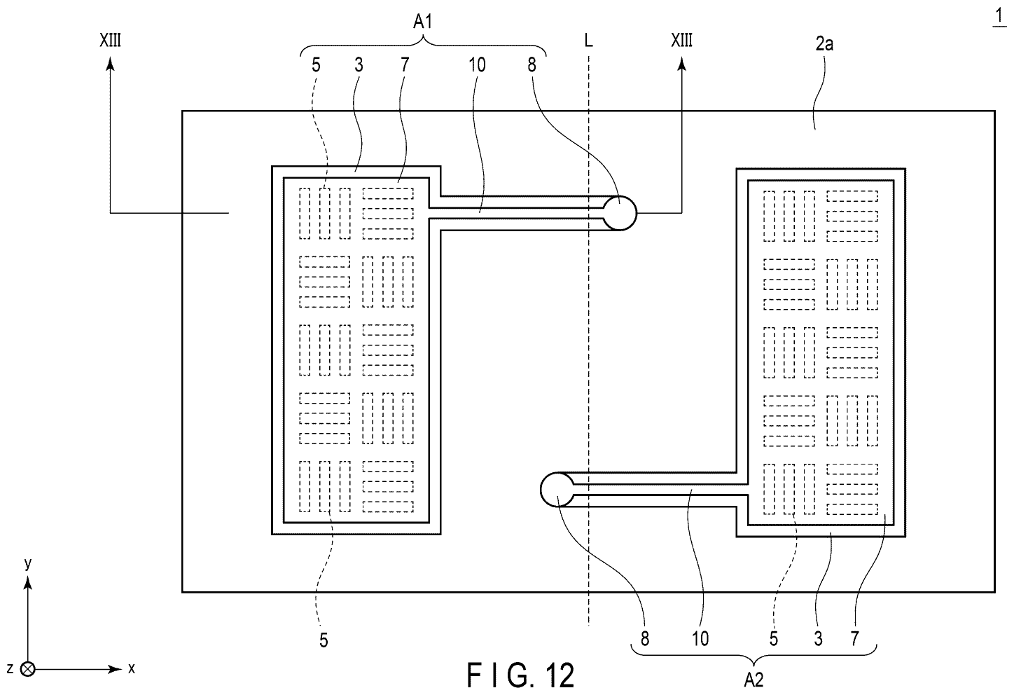

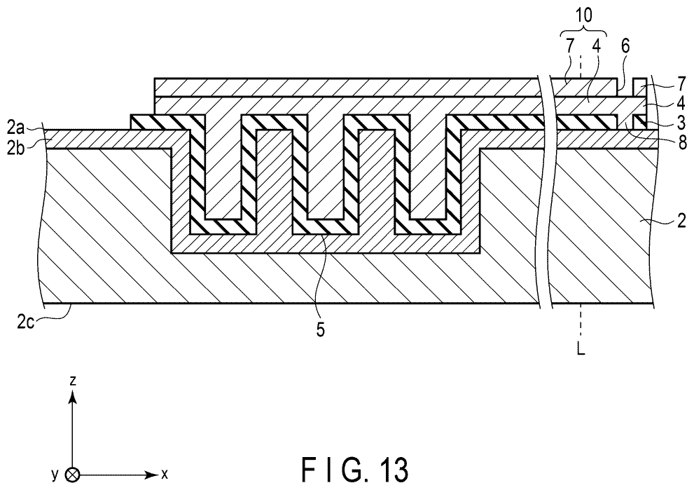

The fifth step includes patterning the dielectric layer 3 by dry etching. The fifth step will be described with reference to FIGS. 12 to 13. FIG. 12 is a plan view of the processing target substrate. FIG. 13 is a sectional view of the processing target substrate shown in FIG. 12 and shows a cross-section taken along the line XIII-XIII.

For each of the capacitor element portions A1 and A2 of the processing target substrate 1, the dielectric layer 3 is processed into a patterned shape by dry etching. The dry etching may be performed after mask formation by photolithography. The patterning is performed for the purpose of partitioning the dielectric layer 3 formed on the entire main surface 2a of the semiconductor substrate 2 for each capacitor element portion or each chip. The partitioned dielectric layer 3 may have a target area for one chip. The dielectric layer 3 is removed by dry etching, except a part where the first conductive layer 4 and the second conductive layer 7 are formed and a part where the connection portion 10 is formed. The fuse portion (poly-Si fuse portion) 8 has the electrical connection state E2 as in the third step.

Examples of the dry etching here may include the same etching techniques discussed for the third step.

The dry etching is conducted with the processing target substrate 1 held by the electrostatic chuck (ESC chuck). After the dry etching, charges that remain in the first conductive layer 4 and the second conductive layer 7 can be allowed to flow from the fuse portion 8 to the semiconductor substrate 2 and escape from the semiconductor substrate 2 to the stage at the time of detaching the processing target substrate 1 from the electrostatic chuck using the pushing-up action of the conductive lift pin, and therefore, it is possible to avoid the occurrence of damage in detaching the processing target substrate 1 from the electrostatic chuck.

### Sixth Step

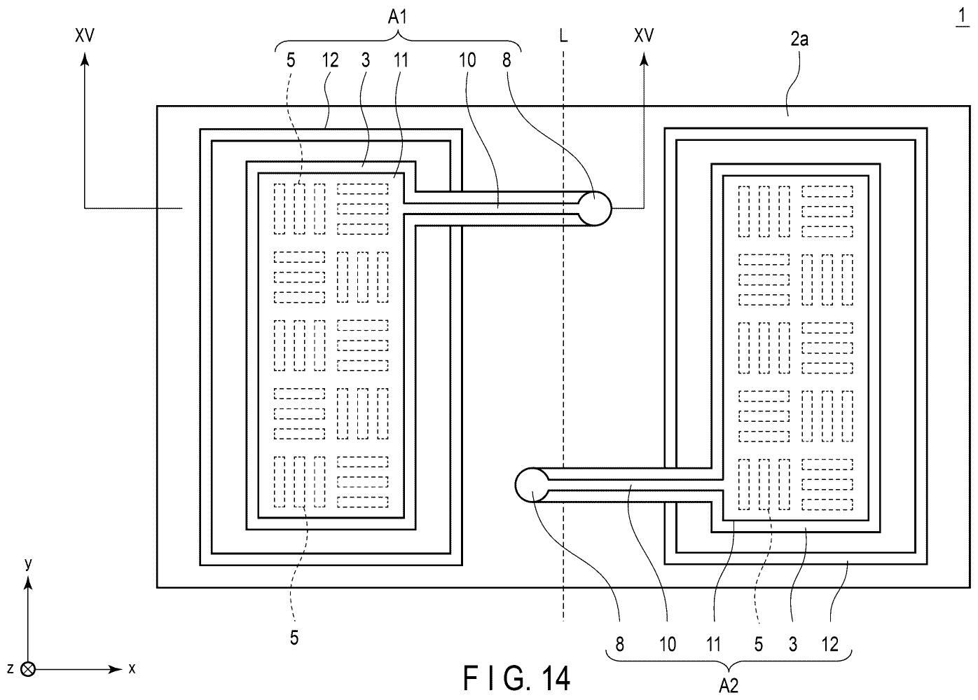

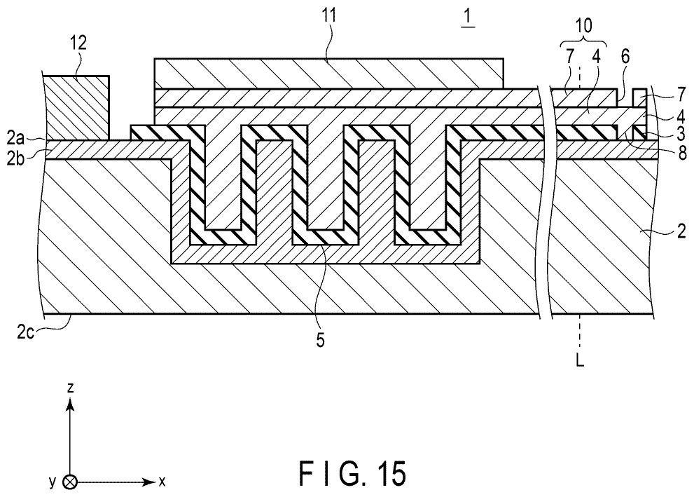

The sixth step includes providing a first contact electrode for the conductive layers and a second contact electrode for the semiconductor substrate. The first contact electrode and the second contact electrode may be sequentially formed from one of them, or may be formed altogether at the same time. The sixth step will be described with reference to FIGS. 14 to 15. FIG. 14 is a plan view of the processing target substrate. FIG. 15 is a sectional view of the processing target substrate shown in FIG. 14 and shows a cross-section taken along the line XV-XV.

For each of the capacitor element portions A1 and A2 of the processing target substrate 1, the conductive layers include the first conductive layer 4 and the second conductive layer 7. A first contact electrode 11 is provided on the xy plane of the second conductive layer 7. A second contact electrode 12 is provided on the main surface 2a of the semiconductor substrate 2.

The first contact electrode 11 and the second contact electrode 12 are each formed of, for example, a metal such as aluminum. In one example, each of the first contact electrode 11 and the second contact electrode 12 is obtained through film formation by sputtering. With the sputtering technique, batch formation of the first contact electrode 11 and the second contact electrode 12 is enabled, and accordingly, the number of processing steps for the manufacture can be reduced.

A barrier layer may be provided for the second conductive layer 7 and the semiconductor substrate 2 before the Al sputtering. The barrier layer may be formed of, for example, Ti or TiN. The barrier layer may be formed by, for example, sputtering.

### Seventh Step

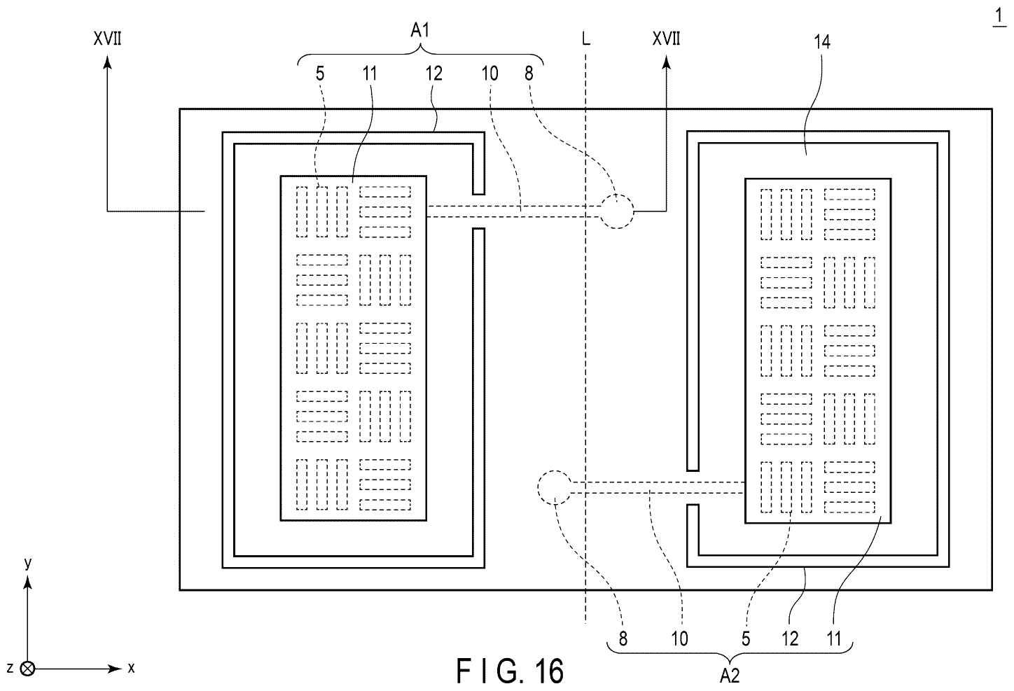

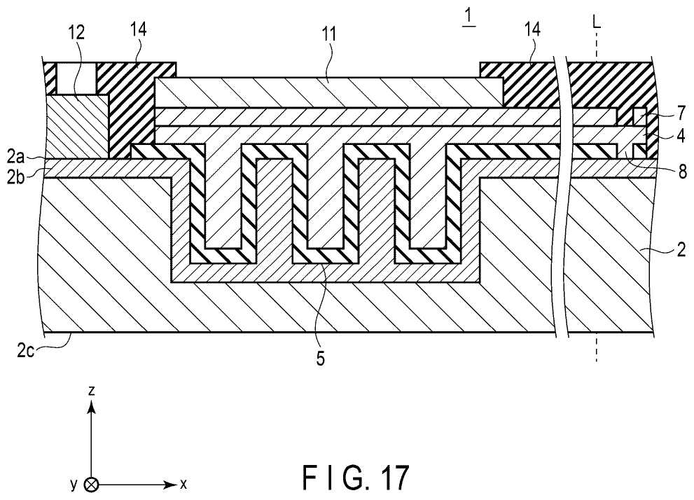

The seventh step includes forming an insulating layer (first insulating layer). The seventh step will be described with reference to FIGS. 16 to 17. FIG. 16 is a plan view of the processing target substrate. FIG. 17 is a sectional view of the processing target substrate shown in FIG. 16 and shows a cross-section taken along the line XVII-XVII.

For each of the capacitor element portions A1 and A2 of the processing target substrate 1, a first insulating layer 14 is provided at target positions of the processing target substrate 1 so as to insulate each of the first contact electrode 11, the second contact electrode 12, the fuse portion 8, and the connection portion 10. As shown in FIG. 16, the first insulating layer 14 is provided over the main surface of the processing target substrate 1, except parts corresponding to the first contact electrode 11 and the second contact electrode 12 of each of the capacitor element portions A1 and A2. The first insulating layer 14 may also be called an “interlayer insulating film. ” In one example, the first insulating layer 14 is formed of an insulating material such as tetraethoxysilane (TEOS), polyethylenimine (PI), or the like.

The fuse portion 8 has the state E2 as in the sixth step.

### Eighth Step

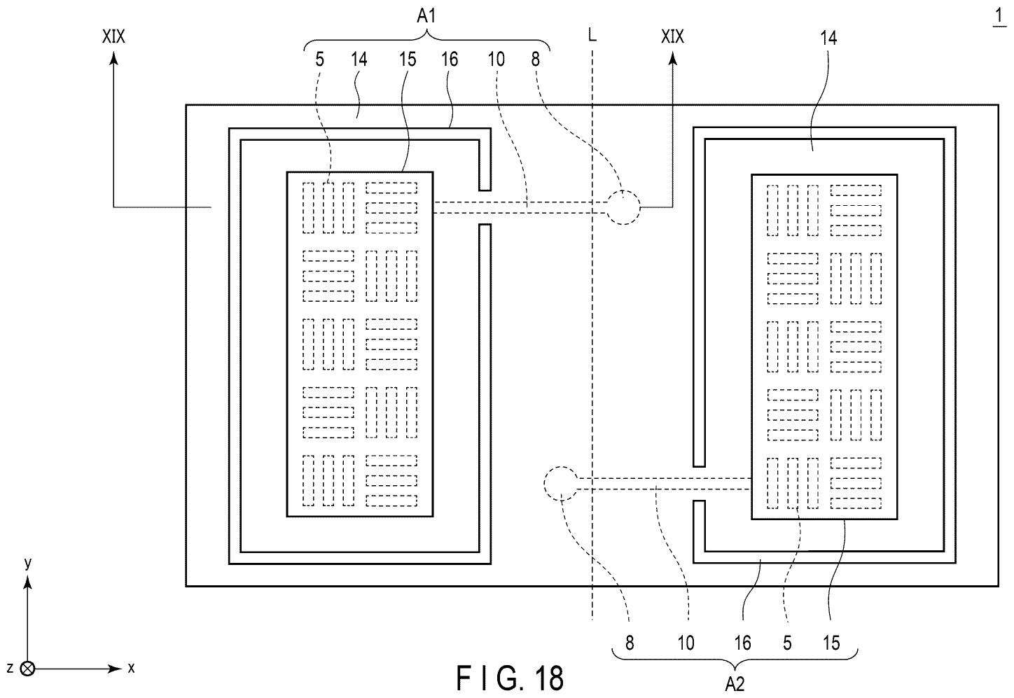

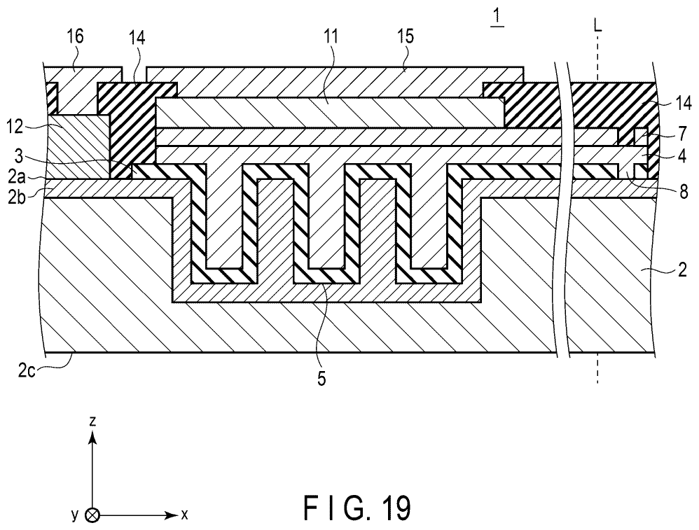

The eighth step includes providing a first pad electrode for the first contact electrode and a second pad electrode for the second contact electrode. The first pad electrode and the second pad electrode may be sequentially formed in this order or a reverse order, or may be formed altogether at the same time. The eighth step will be described with reference to FIGS. 18 to 19. FIG. 18 is a plan view of the processing target substrate. FIG. 19 is a sectional view of the processing target substrate shown in FIG. 18 and shows a cross-section taken along the line XIX-XIX.

For each of the capacitor element portions A1 and A2 of the processing target substrate 1, a first pad electrode 15 is provided to be in contact with the xy plane of the first contact electrode 11 and electrically connected to the first contact electrode 11. A second pad electrode 16 is provided to be in contact with the xy plane of the second contact electrode 12 and electrically connected to the second contact electrode 12.

The first pad electrode 15 and the second pad electrode 16 are each formed of, for example, a metal such as aluminum. In one example, each of the first pad electrode 15 and the second pad electrode 16 is obtained through film formation by sputtering.

While FIG. 19 shows a boundary between the first contact electrode 11 and the first pad electrode 15 and between the second contact electrode 12 and the second pad electrode 16 for facilitating understanding, it is not always the case that such boundaries (interfaces) appear. A first electrode may be constituted by at least one of the first contact electrode 11 or the first pad electrode 15. Also, a second electrode may be constituted by at least one of the second contact electrode 12 or the second pad electrode 16.

### Ninth Step

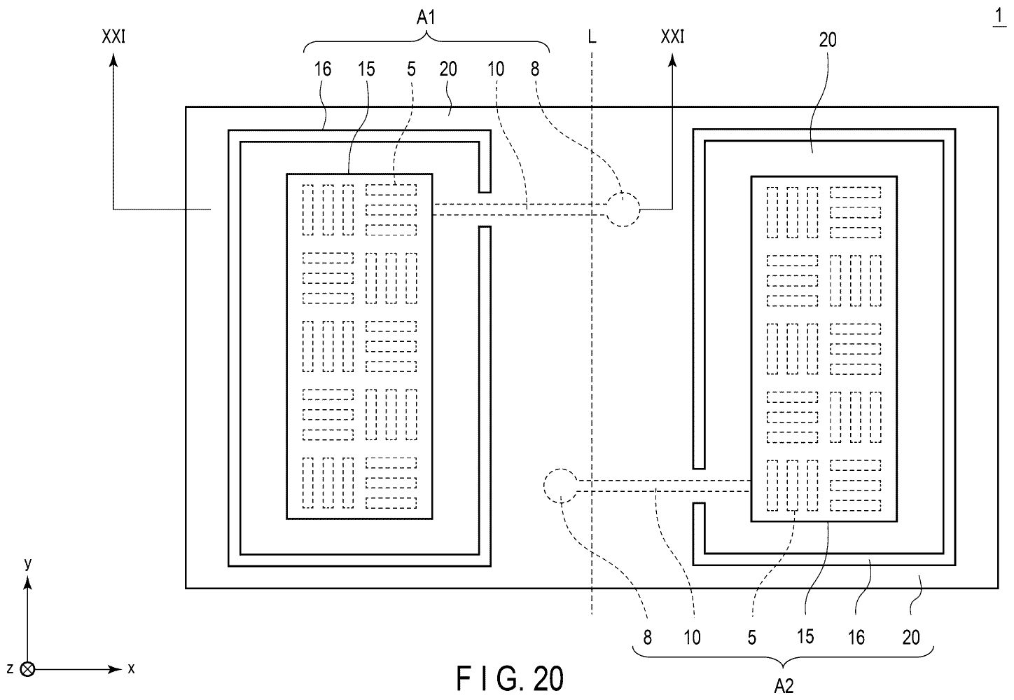

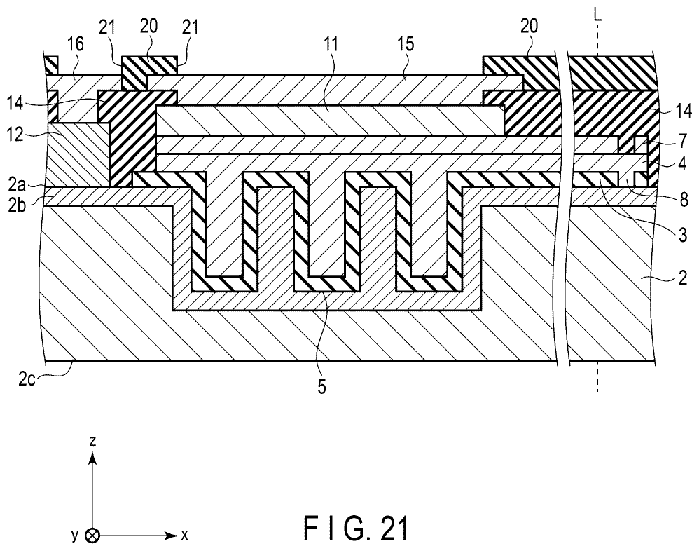

The ninth step includes providing an insulating layer (second insulating layer). The ninth step will be described with reference to FIGS. 20 to 21. FIG. 20 is a plan view of the processing target substrate. FIG. 21 is a sectional view of the processing target substrate shown in FIG. 20 and shows a cross-section taken along the line XXI-XXI.

As shown in FIG. 20, a second insulating layer 20 is provided over the main surface of the processing target substrate 1, except parts corresponding to the first pad electrode 15 and the second pad electrode 16 of each of the capacitor element portions A1 and A2. As shown in FIG. 21, openings 21 are provided in the xy plane of the second insulating layer 20. The first pad electrode 15 and the second pad electrode 16 are located in the respective openings 21 of the second insulating layer 20. The first pad electrode 15 and the second pad electrode 16 are electrically insulated from each other by the second insulating layer 20 interposed therebetween. Here, the second insulating layer 20 surrounds the outer walls of the second pad electrode 16. Also, the second insulating layer 20 is provided on the first insulating layer 14 that covers the connection portion 10 and the fuse portion 8. In one example, the second insulating layer 20 is formed of an insulating material such as tetraethoxysilane (TEOS), polyethylenimine (PI), or the like.

While FIG. 21 shows a boundary between the first insulating layer 14 and the second insulating layer 20 for facilitating understanding, it is not always the case that such a boundary (interface) appears.

### Tenth Step

The tenth step includes cutting the processing target substrate 1 along the dicing lines to divide it into multiple capacitor element portions. The tenth step will be described with reference to FIG. 20.

The processing target substrate 1 is cut along the dicing line L so as to be divided into the multiple capacitor element portions A1 and A2. The connection portions 10, which are parallel to each other and extend in the x-axis direction from the respective capacitor element portions A1 and A2, cross the dicing line L. As such, cutting along the dicing line L breaks the electrical connection between the connection portion 10 extending from the capacitor element portion A1 and the corresponding fuse portion 8, and also the electrical connection between the connection portion 10 extending from the capacitor element portion A2 and the corresponding fuse portion 8. As a consequence, the capacitor element portions A1 and A2 each return to the state E1 in which the original MIM capacitor is formed. By dividing the processing target substrate 1 into multiple pieces, multiple capacitor element portions can be manufactured. Note that the cutting position of each connection portion 10 is not limited to the vicinity of the fuse portion 8, and the connection portion 10 may be cut at any position.

The dicing is not limited to a particular method and the cutting may employ any technique such as laser dicing, stealth dicing, plasma dicing, or blade dicing.

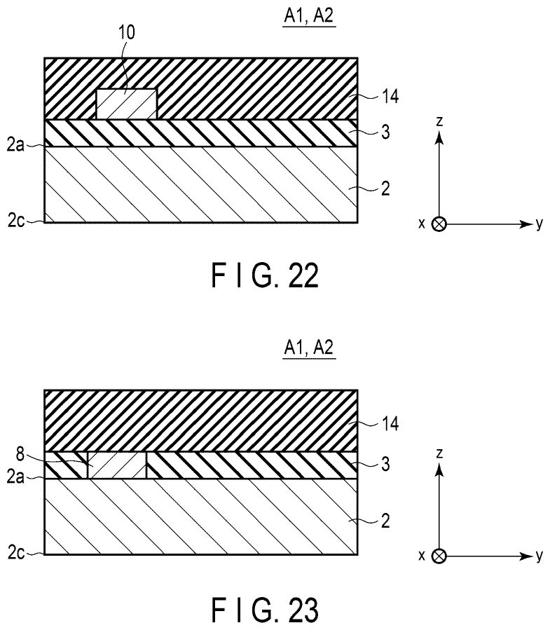

With the method including the foregoing first to tenth steps, one or more capacitor element portions A1 and A2 can be obtained. Among the cross-sections of each of the capacitor element portions A1 and A2 that are taken parallel to the dicing line L, a schematic cross-section covering the vicinity of the connection portion 10 is given as FIG. 22, and a schematic cross-section covering the vicinity of the fuse portion 8 is given as FIG. 23. Each of the capacitor element portions A1 and A2 includes the semiconductor substrate 2 having the main surface 2a with one or more recesses 5, the conductive layers 4 and 7 provided in each of the recesses 5 and over the main surface 2a of the semiconductor substrate 2, the dielectric layer 3 arranged between the set of the conductive layers 4 and 7 and the semiconductor substrate 2, the connection portion 10 directly extending from one or more parts of the conductive layers 4 and 7, and the opening 6 of which a bottom wall is the main surface 2a of the semiconductor substrate 2. As shown in FIG. 22, in the cross-section taken along the thickness direction z of each of the capacitor element portions A1 and A2, the connection portion 10 is located on the dielectric layer 3 and surrounded and insulated by the first insulating layer 14. Also, as shown in FIG. 23, in the cross-section taken along the thickness direction z of each of the capacitor element portions A1 and A2, the conductive material of the fuse portion 8 is located within the opening provided in the dielectric layer 3. The opening filled with the conductive material is separate from the connection portion 10. Thus, the fuse portion 8 is not electrically connected to the connection portion 10. Note that, depending on etching conditions, the opening may be formed in such a form as to reach the semiconductor substrate 2 beyond the dielectric layer 3. In such instances, the fuse portion 8 may also be embedded in the semiconductor substrate 2.

The method including the first to tenth steps assumes formation of insulating layers over the boundary between the capacitor element portions, where the dicing line L is present, and its vicinity. However, this is an example which intends no limitation. The insulating layers over the boundary between the capacitor element portions A1 and A2 and its vicinity may be omitted.

Also, the embodiments may include a complete set of the first to tenth steps or may omit some of the steps. The first to tenth steps may include, between any steps among them, one or more other steps such as formation of a mask layer, formation of a barrier layer, and washing.

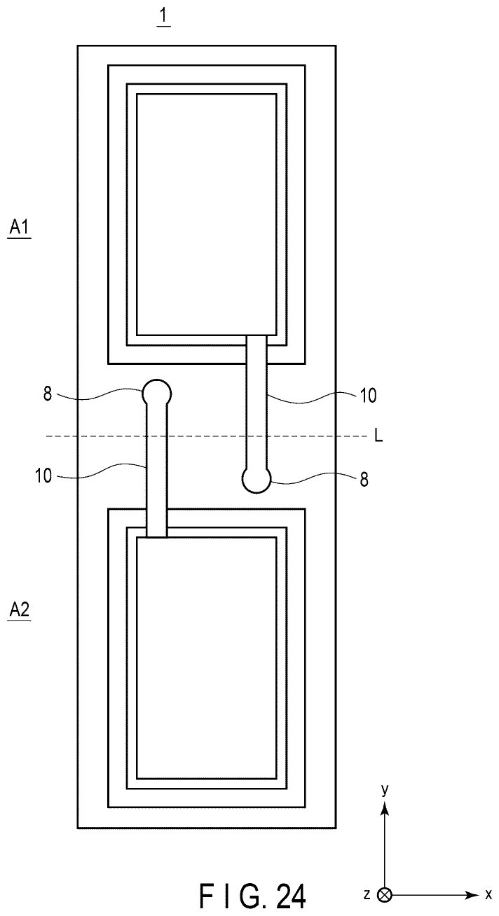

The description with reference to FIGS. 1 to 23 has assumed an example where the capacitor element portions A1 and A2 are next to each other in the x-axis direction, but no limitation is intended by this. Another example is shown in FIGS. 24 to 26. FIG. 24 shows the capacitor element portions A1 and A2 which are arranged next to each other in the y-axis direction. The capacitor element portion A1 and the capacitor element portion A2 share the side along the x-axis direction. The shared side is located along the dicing line L. The connection portion 10 extending from the capacitor element portion A1 is electrically connected to the fuse portion 8 in the capacitor element portion A2. Also, the connection portion 10 extending from the capacitor element portion A2 is electrically connected to the fuse portion 8 in the capacitor element portion A1. After the dry process such as dry etching, the processing target substrate can be detached from the electrostatic chuck without incurring damage such as cracks. Also, the connection portion 10 extends in the direction parallel to the y-axis direction and crossing the direction of the dicing line L. The connection portion 10 and the fuse portion 8 can be electrically disconnected from each other by cutting the processing target substrate along the dicing line L to divide the processing target substrate into capacitor element portions.

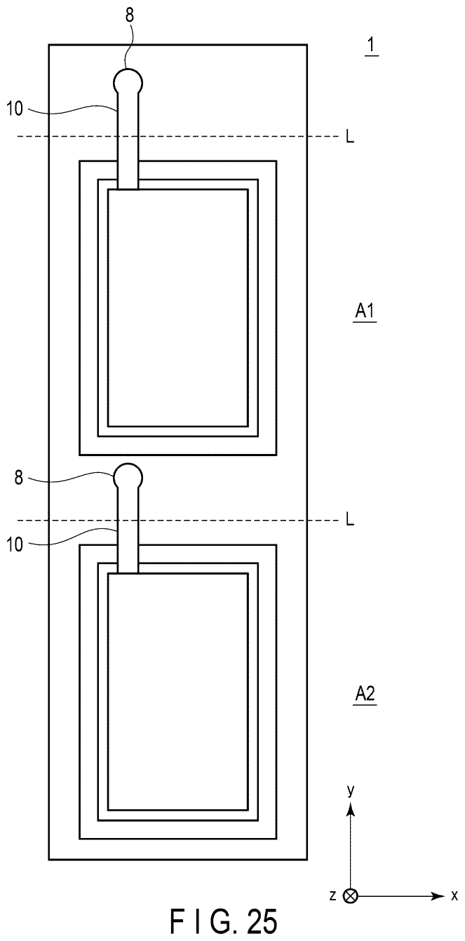

While FIG. 24 shows an example where the connection portion 10 from the capacitor element portion A1 and the connection portion 10 from the capacitor element portion A2 extend in opposite directions, the connection portion 10 from the capacitor element portion A1 and the connection portion 10 from the capacitor element portion A2 may extend in the same direction as shown in FIG. 25.

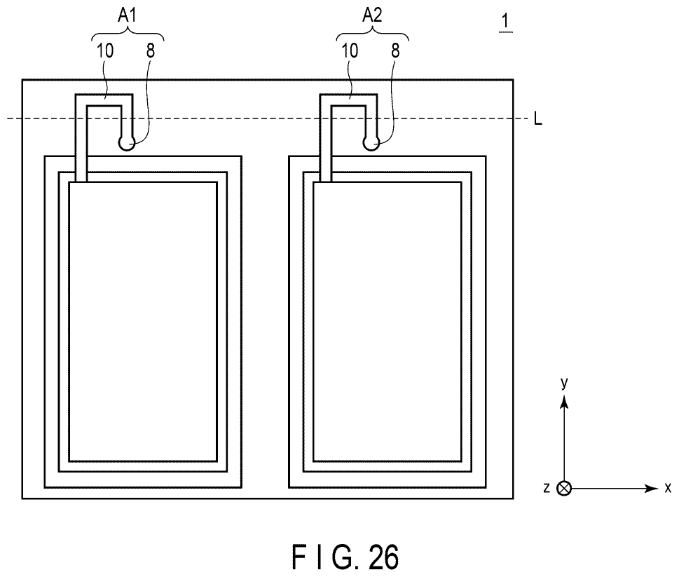

FIG. 26 shows an example where the capacitor element portions A1 and A2 are arranged next to each other in the x-axis direction. The connection portions 10 of the capacitor element portions A1 and A2 are each bent in the direction opposite to their extending direction (along the y-axis direction). The end of the connection portion 10 of each of the capacitor element portions A1 and A2 is electrically connected to the fuse portion 8 provided for the same capacitor element portion. The dicing line L is provided to be parallel to the x-axis direction of the processing target substrate 1 and cross the extending direction of the connection portions 10. In the state where the connection portion 10 and the corresponding fuse portion 8 are electrically connected to each other, the processing target substrate can be detached from the electrostatic chuck after the dry process such as dry etching, without incurring damage such as cracks. Also, the connection portion 10 and the fuse portion 8 can be electrically disconnected from each other by cutting the processing target substrate along the dicing line L to divide the processing target substrate into capacitor element portions.

The method and the capacitor according to the embodiments are applicable to, for example, a capacitor including a Si wafer having a diameter of 8 inches or more as a semiconductor substrate (as one example, a capacitor for use in a memory such as a DRAM).

According to the method of at least one of the foregoing embodiments, the conductive layers are processed into a pattern shape by dry etching, and then an electrical connection between the semiconductor substrate and the conductive layer is established through the conductive material portion and the connection portion. Therefore, the processing target substrate can be detached from the electrostatic chuck without incurring damage such as cracks. Moreover, the cutting position for cutting and dividing the processing target substrate to manufacture one or more capacitor element portions is set to include a position where the connection portion is cut in the direction crossing its extending direction, so as to allow the breakage of the electrical connection between the connection portion and the conductive material portion. Therefore, with the method and the capacitor according to the embodiments, damage such as cracks to the processing target substrate can be reduced without complicating the involved steps.

While certain embodiments have been described, they have been presented by way of example only, and are not intended to limit the scope of the inventions. Indeed, the novel embodiments described herein may be embodied in a variety of other forms. Furthermore, various omissions, substitutions, and changes in the form of the embodiments may be made without departing from the spirit of the inventions. The accompanying claims and their equivalents are intended to cover such forms or modifications as would fall within the scope and spirit of the inventions.

What is claimed is:

1. A method of manufacturing a capacitor, the capacitor comprising at least one capacitor element portion, the at least one capacitor element portion comprising a semiconductor substrate having a main surface with one or more recesses, a conductive layer provided for the main surface and the one or more recesses of the semiconductor substrate, a dielectric layer between the conductive layer and the semiconductor substrate, a first electrode electrically connected to the conductive layer, and a second electrode electrically connected to the semiconductor substrate, the method comprising:
providing, in a processing target substrate including the semiconductor substrate, the conductive layer, and the dielectric layer, one or more openings in the dielectric layer and the conductive layer present in the main surface of the semiconductor substrate;
providing a conductive material portion on the main surface located within the one or more openings;
subjecting the conductive layer to dry etching to form a pattern including a connection portion extending from the conductive layer to the one or more openings;
providing the first electrode electrically connected to the conductive layer and the second electrode electrically connected to the semiconductor substrate; and
cutting the processing target substrate along a cutting position which includes a position where the connection portion is cut in a direction crossing an extending direction of the connection portion, so as to have the connection portion and the conductive material portion electrically disconnected from each other and to manufacture the at least one capacitor element portion.

2. The method according to claim 1, wherein the cutting comprises performing at least one of laser dicing, stealth dicing, plasma dicing, or blade dicing.

3. The method according to claim 1, wherein the processing target substrate before the cutting comprises a plurality of the at least one capacitor element portion in which the connection portion extending from the conductive layer of a first capacitor element portion is connected to the one or more openings of a second capacitor element portion next to the first capacitor element portion.

4. The method according to claim 1, wherein the semiconductor substrate is a Si-containing substrate, and the conductive layer and the conductive material portion each contain poly-Si.

5. The method according to claim 1, wherein the dry etching is conducted with the processing target substrate held by an electrostatic chuck.

6. The method according to claim 5, wherein the dry etching comprises chemical dry etching.

7. The method according to claim 5, which comprises detaching the processing target substrate from the electrostatic chuck after the dry etching.

8. The method according to claim 1, which comprises subjecting the dielectric layer of the processing target substrate to dry etching with the processing target substrate held by an electrostatic chuck.

9. The method according to claim 8, which comprises detaching the processing target substrate from the electrostatic chuck after the dry etching.

10. A capacitor comprising:
a semiconductor substrate having a main surface with one or more recesses;
a conductive layer provided in the one or more recesses and the main surface of the semiconductor substrate;
a dielectric layer between the conductive layer and the semiconductor substrate;
a connection portion connected to the conductive layer that is located in the main surface of the semiconductor substrate;
an opening separate from the connection portion and having a bottom wall which is located in the main surface of the semiconductor substrate; and
a conductive material portion provided in the opening.

11. The capacitor according to claim 10, wherein the semiconductor substrate is a Si-containing substrate, and the conductive layer and the conductive material portion each contain poly-Si.
